(19) United States
(12) Patent Application Publication
(10) Pub. No.: US 2026/0277276 A1
(43) Pub. Date: Sep. 17, 2026

(54) Part Retention

(71) Applicants: Tung Yuen LAU, Redmond, WA (US); Microsoft Technology Licensing, LLC, Redmond, WA (US)

(72) Inventors: Tung Yuen Lau, Hong Kong (CN); Shuanghu Zhang, Suzhou city (CN)

(73) Assignee: Microsoft Technology Licensing, LLC, Redmond, WA (US)

(21) Appl. No.: 19/167,958

(22) PCT Filed: Apr. 3, 2023
(86) PCT No.: PCT/CN2023/085874

§ 371 Date: Sep. 23, 2025

(51) Int. Cl. G06F 1/16; H05K 5/02

(52) U.S. Cl. CPC G06F 1/166; H05K 5/0221; H05K 5/0234

(57) ABSTRACT

The description relates to devices that have removable parts, such as feet or pads. One example can include a housing containing electronic components and a receptacle positioned in the housing. A foot assembly can be positioned in the receptacle. The foot assembly can include a locking mechanism that mechanically blocks removal of the foot assembly from the receptacle unless acted upon by a magnetic field that rearranges the locking mechanism and unblocks removal of the foot assembly from the receptacle.

### BACKGROUND

Traditionally, devices, such as computing devices that are configured to contact various work surfaces include elastic polymer feet or pads.

### SUMMARY

This patent relates to devices that have removable parts, such as feet or pads. One example can include a housing containing electronic components and a receptacle positioned in the housing. A foot assembly can be positioned in the receptacle. The foot assembly can include a locking mechanism that mechanically blocks removal of the foot assembly from the receptacle unless acted upon by a magnetic field that rearranges the locking mechanism and unblocks removal of the foot assembly from the receptacle.

This summary is intended to provide a brief introduction to some of the concepts described in this document and is not intended to be inclusive or limiting.

### BRIEF DESCRIPTION OF THE DRAWINGS

The accompanying drawings illustrate implementations of the concepts conveyed in the present document. Features of the Illustrated implementations can be more readily understood by reference to the following description taken in conjunction with the accompanying drawings. Like reference numbers in the various drawings are used wherever feasible to indicate like elements. Further, the left-most numeral of each reference number conveys the figure and associated discussion where the reference number is first introduced.

FIG. 1 is a perspective view of an example secure part retention system in accordance with the present concepts.

FIG. 2A is an elevational view of an example secure part retention implementation in accordance with the present concepts.

FIGS. 2B, 3A-3E, and 4A-4E are sectional views of example secure part retention implementations in accordance with the present concepts.

FIGS. 2C and 2D are sectioned perspective views of example secure part retention implementations in accordance with the present concepts.

FIG. 2E is an exploded elevational view corresponding to FIG. 2A of example secure part retention implementations in accordance with the present concepts.

FIG. 2F is an exploded sectional view corresponding to FIG. 2B of example secure part retention implementations in accordance with the present concepts.

### DESCRIPTION

The present concepts relate to devices, such as computing devices that can include components positioned in an enclosure or housing. The present concepts include technical solutions for removably securing parts to the housing. In one case, the part can be a foot that includes an exposed pad. One or more feet can be removably secured to the device. The feet can be mechanically blocked from being removed from the device to provide a high retention force. In the event that it is desired to remove individual feet, a magnet can be positioned against an individual foot to mechanically unblock the individual foot for removal. The individual foot can be removed and re-installed through repeated cycles without experiencing a reduction in the retention force as would occur with traditional elastomeric polymer feet.

Some of the present technical solutions entail a locking mechanism that defaults to a locked position or locked state that mechanically locks the part, such as a foot, and blocks removal from the device. The locking mechanism can be transitioned to an unlocked position or unlocked state with a magnet when removal is desired. The locking mechanism can be subjected to a force from a biasing member that biases the locking mechanism to the locked position. Positioning a magnet proximate to the part can overcome the force and transition the locking mechanism to the unlocked position. In the unlocked position the part can be readily removed from the device. The part can be re-installed and is automatically locked in the device when the magnet is removed. When the magnet is removed, the force from the biasing member transitions the locking mechanism back to the locked position.

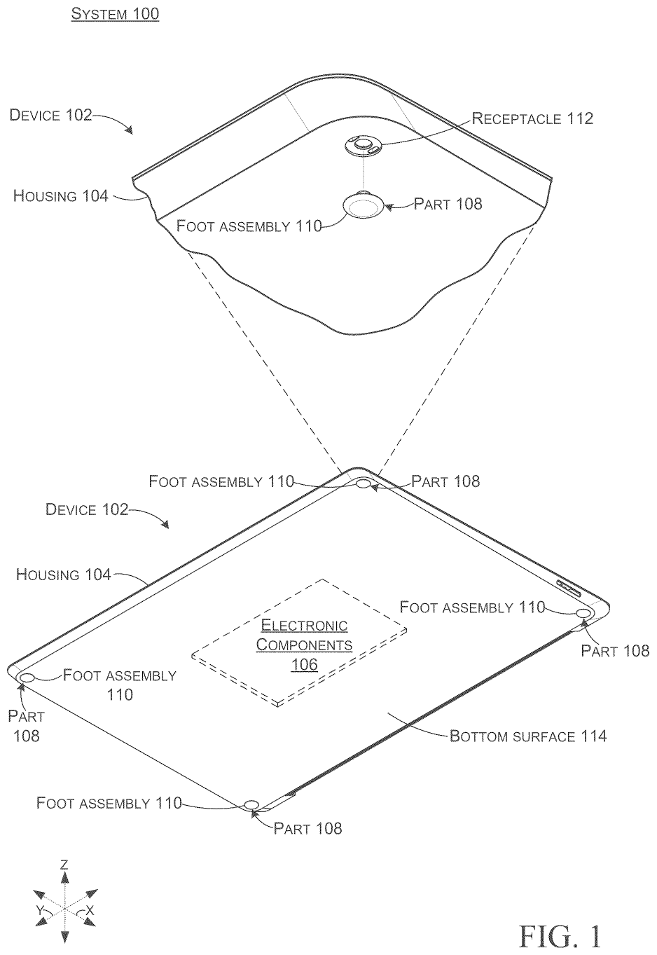

FIG. 1 shows an example system 100 which can apply the present secure part retention concepts. In this case, system 100 includes device 102. The device 102 includes a housing 104 that contains electronic components 106. The electronic components 106 are shown in ghost (e.g., dashed) to indicate they would be occluded by the housing 104. Parts 108, such as foot assemblies 110, can be secured to receptacles 112 in the housing 104. For instance, in this case, receptacles 112 are positioned on a bottom surface 114 of the housing 104. Foot assemblies 110 can be positioned in the receptacles 112 to protect the device and/or to provide a secure purchase on surfaces upon which the device may be placed.

Traditional feet are formed from elastomeric materials that are inserted into a tapered receptacle. Retention is accomplished by compression of the elastomeric materials during insertion and subsequent expansion against the receptacle. The elastomeric feet have limited retention strength and can be pulled out during normal activities, such as putting a notebook computer into a backpack, The traditional elastomeric feet can also be purposely removed. However, with each removal and re-insertion the retention strength diminishes, such that at some point the feet may simply fall out.

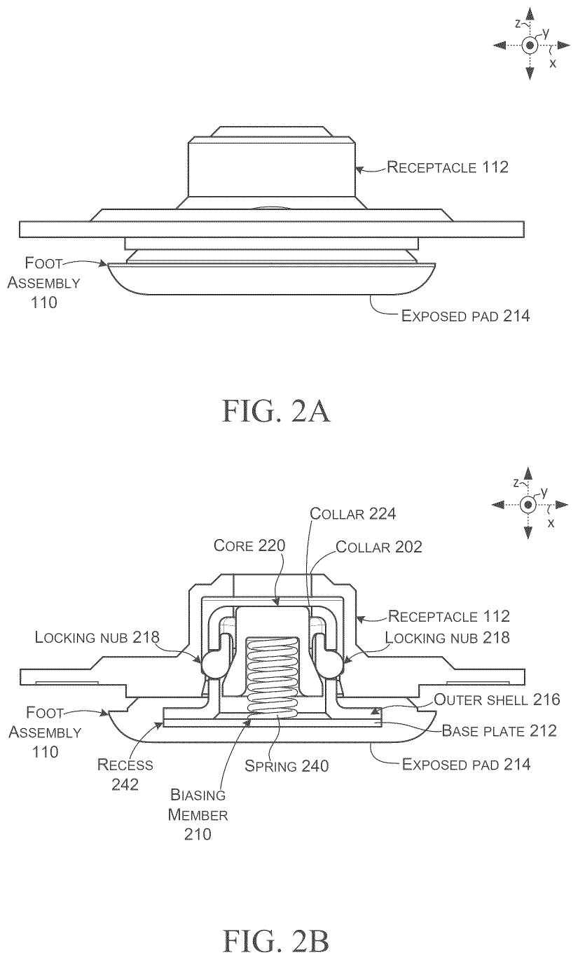

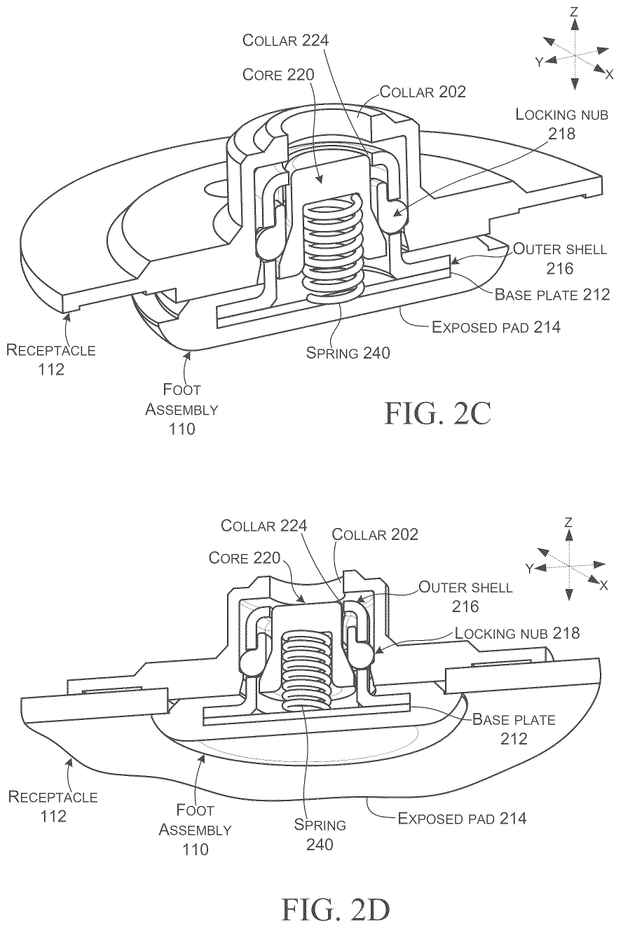

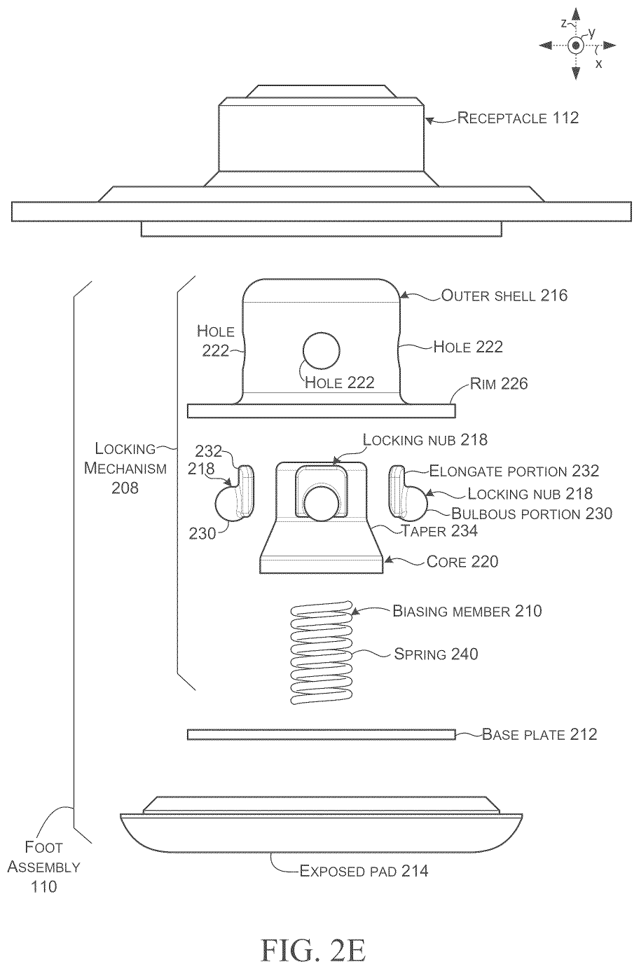

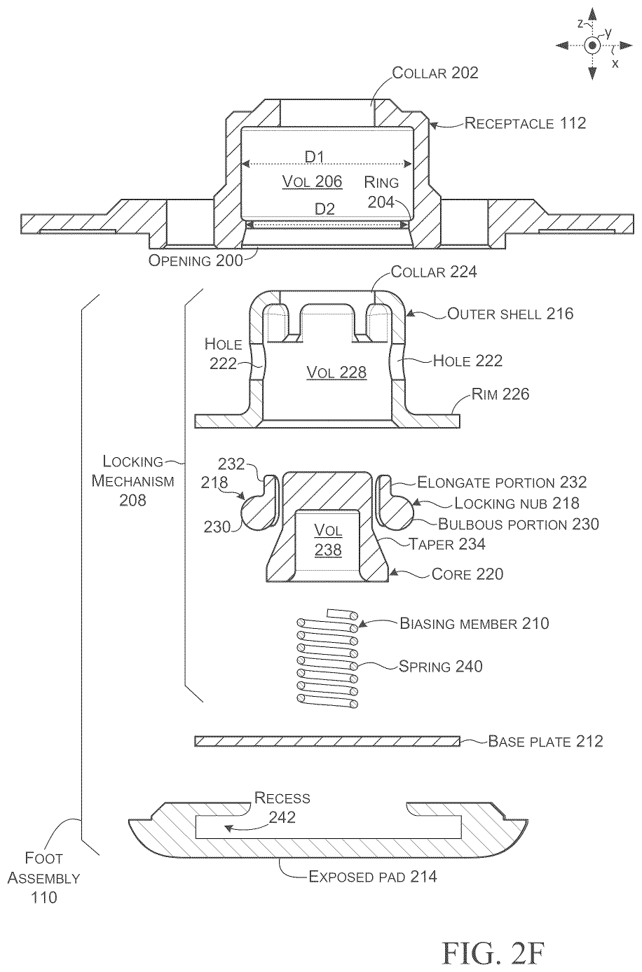

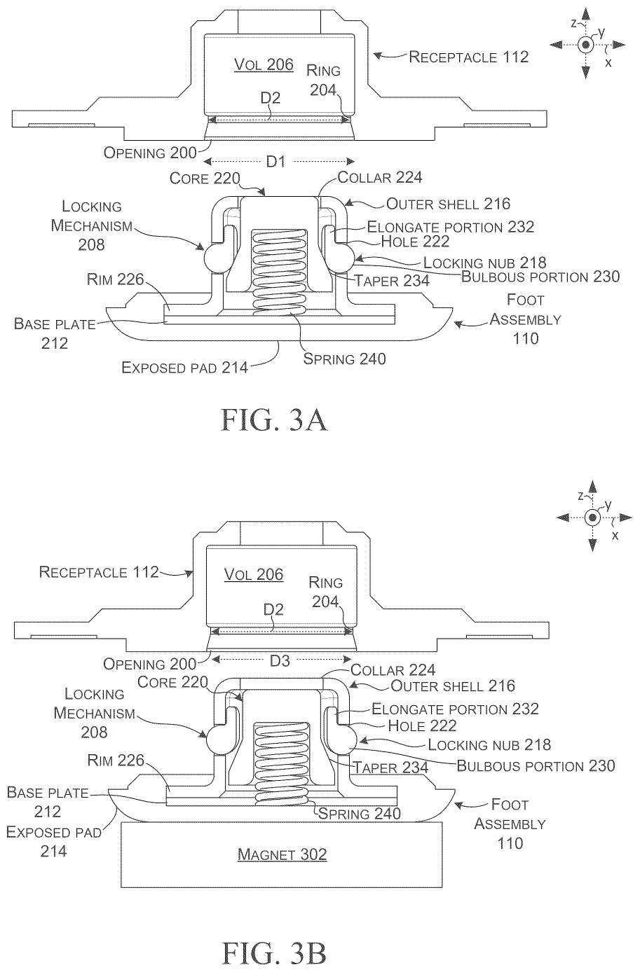

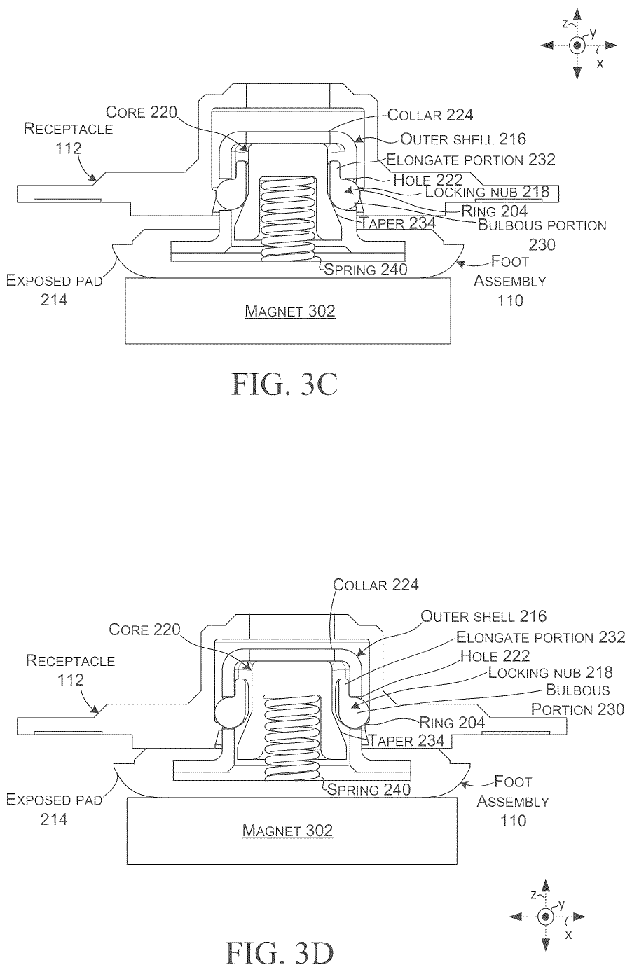

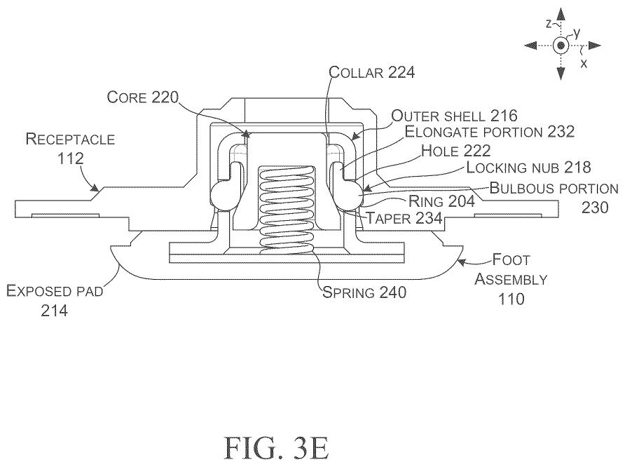

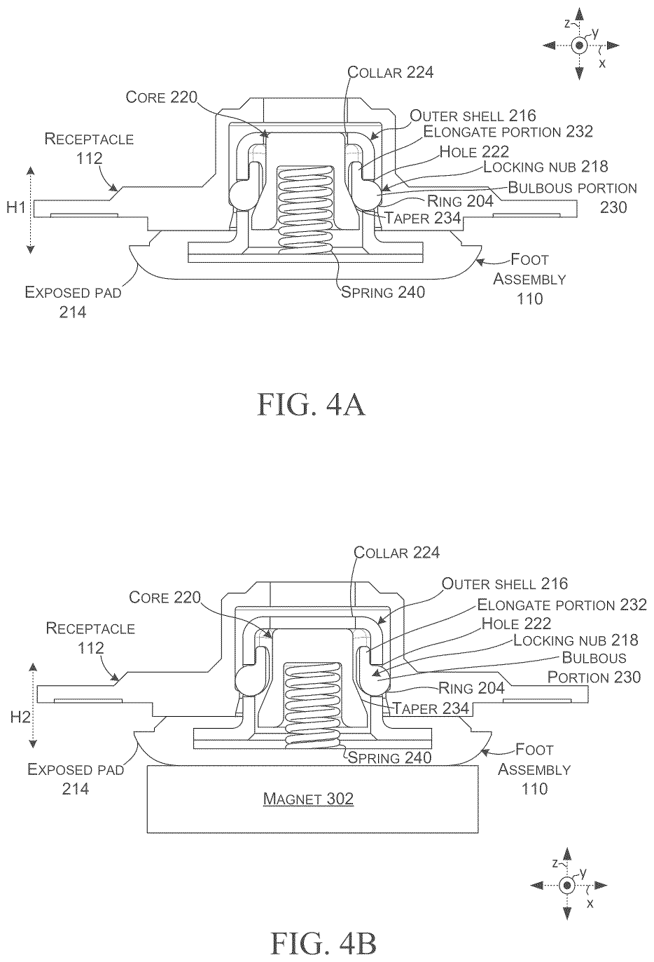

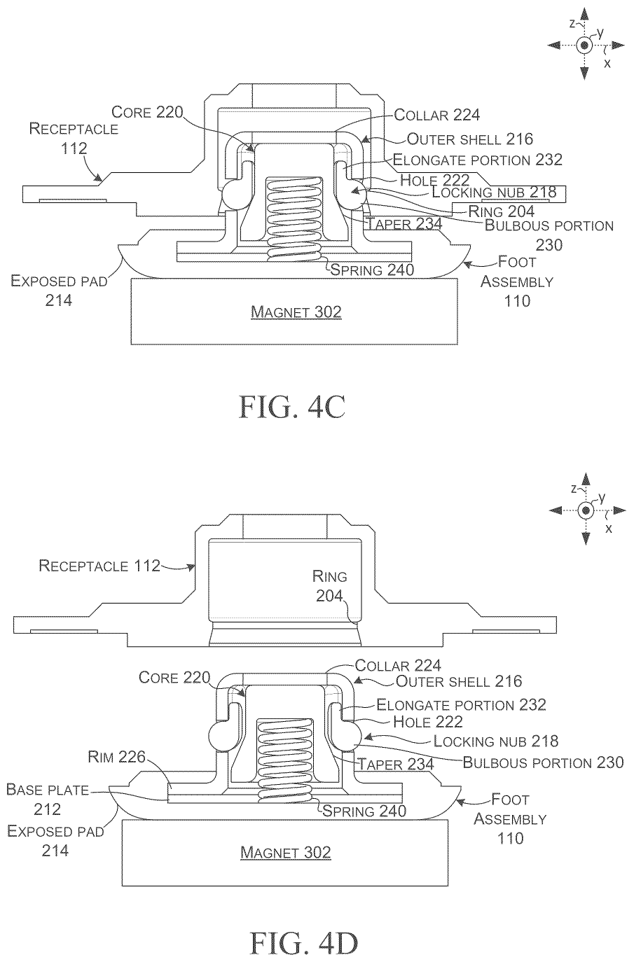

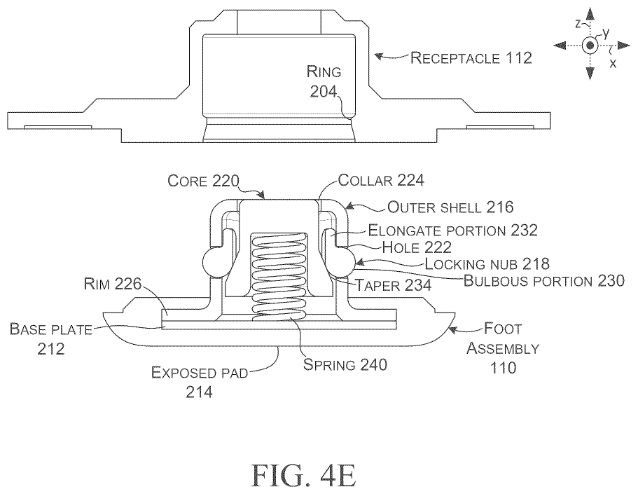

In contrast, the present concepts provide a technical solution for parts 108 such as foot assemblies 110 that mechanically lock in the receptacle 112. The mechanical lock provides greater retention strength than traditional designs. An individual foot assembly 110 can be unlocked with a magnet for easy removal from the receptacle. The foot assembly can be re-installed and locked in the receptacle and will have/maintain the original high retention strength. FIGS. 2A-2F introduce an example foot assembly that provides these and other technical solutions. FIGS. 3A-4E collectively show the locking and unlocking aspects of the example foot assembly of FIGS. 2A-2F.

FIGS. 2A-2F collectively show elements of example foot assembly 110 and receptacle 112. FIG. 2A is side elevational view of the example foot assembly 110 and receptacle 112. FIG. 2B is a corresponding side sectional view of the example foot assembly 110 and receptacle 112. FIGS. 2C and 2D are complementary sectional perspective views. FIG. 2E is an exploded side elevational view of the example foot assembly 110 and receptacle 112. FIG. 2F is an exploded side sectional view of the example foot assembly 110 and receptacle 112.

In this case, receptacle 112 defines an opening 200 (FIG. 2F), a collar 202, and a constraint in the form of a ring 204 (FIG. 2F), which in part define an internal volume 206 (FIG. 2F). Stated another way, the constraint (e.g., ring 204) is interposed between the opening 200 and the volume 206. Thus, the volume 206 is bounded in part by the ring 204, such that entry into and/or out of the volume 206 must pass through the constraint.

In this implementation, the foot assembly 110 includes a locking mechanism 208 (FIGS. 2E and 2F), a biasing member 210 (FIGS. 28, 2E, and 2F), a base plate 212 (FIGS. 2B, 2E, and 2F), and an exposed pad 214. In this implementation, the exposed pad 214 is manifest as an over-molded cover. In this example, as labelled in FIGS. 2B, 2E, and 2F the locking mechanism 208 includes an outer shell 216, locking nubs 218, and a core 220, as well as the biasing member 210.

The outer shell 216 defines holes 222, a collar 224, a rim 226, and a volume 228 (FIG. 2F). The locking nubs 218 include a bulbous portion 230 and an elongate portion 232 (FIGS. 2E and 2F). In this example, the holes 222 are distributed radially around the reference axis (e.g., the z axis). The bulbous portions 230 are positioned in the holes 222 and thus the locking nubs 218 are positioned radially around the axis at the corresponding locations of the holes 222. In this case, there are four holes 222 and four locking nubs 218 arranged at 90-degree intervals around the axis. Other numbers of locking nubs 218 and holes 222 are contemplated. For instance, three pairs of locking nubs 218 and holes 222 could be arranged at 120-degree intervals, among other configurations.

The core 220 has a taper 234 (FIGS. 2E and 2F) from a wider base (shown but not labelled) that is proximate to the base plate 212 to a narrow top (shown but not labelled) that is distal to the base plate 212. The core 220 also defines a volume 238. The biasing member 210 is manifest as a spring 240 (FIGS. 28, 2D, 2E, and 2F). Other biasing members 210 can entail elastomeric bodies, for instance, When assembled, the spring 240 is nested in volume 238 defined by the core 220. The spring 240 is compressed and retained between the base plate 212 and the core 220. The core 220 in-turn is nested in volume 228 defined by the outer shell 216. Rim 226 of the outer shell 216 and the base plate 212 are retained against one another in a recess 242 of the exposed pad 214. Thus, the elements of the foot assembly 110 are retained by and between the exposed pad 214 and the outer shell 216. Further, the compressed spring 240 creates an upward bias force (e.g., in the positive z reference direction or axis) on the core 220. The upward bias force pushes the core 220 into the collar 224 of the outer shell 216 and towards the collar 202 of the receptacle 112.

Note also, in this implementation, the core 220 has a ferrous metal composition (e.g., is magnetic). In contrast, other elements, such as the outer shell 216, locking nubs 218, and/or base plate 212 can be non-ferrous (e.g., non-magnetic) material. For instance, these latter elements can be formed from non-ferrous metals, such as aluminum, magnesium, etc. or from non-metallic materials, such as ceramics or composites, among others. These aspects will be explained more below relative to FIGS. 3A-3E.

FIGS. 3A-4E collectively show the function of the foot assembly 110. FIG. 3A shows the foot assembly 110 un-installed but ready for installation below the receptacle 112. At this point, the bulbous portions 230 of the locking nubs 218 are positioned in, and extending outwardly through and past, the holes 222. The spring 240 is biasing the core 220 upward into the collar 224 of the outer shell 216. The upward movement of the core 220 is causing the taper 234 to contact the bulbous portions 230 until further upward movement of the core is blocked. The locking nubs 218 cannot move outwardly because the elongate portions 232 are contacting the outer shell 216 and are blocked from further movement. The locking nubs 218 cannot move inwardly because they are blocked by contact with the taper 234 of the core 220. As a result, a biased outer dimension D1 measured transverse the z reference axis from the outside edges of opposing locking nubs 218 is greater than an inside or inner dimension D2 defined by ring 204 of the receptacle 112.

In relation to FIG. 3A, the bias from the spring 240 cannot move the core 220 farther upward because of the increasing diameter presented by the taper 234 contacting the locking nubs 218. The spring 240 cannot move downwardly because it is captive between the core 220 on the upper side and the base plate 212 which is held against the rim 226 by the exposed pad 214 (e.g., the over-molded cover).

FIG. 3B shows the addition of a magnet 302 positioned below the foot assembly 110 against the exposed pad 214. Recall that the core 220 is formed from a magnetic ferrous material. The magnet 302 generates a magnetic field that creates attractive magnetic forces on ferrous materials, such as core 220. At this point magnetic attraction between the magnet 302 and the core 220 has overcome the upward bias created by the spring 240 and moved the core 220 downward (e.g., in the negative z reference direction). The downward movement in the illustrated configuration is approximately equal to the thickness of the outer shell 216 at the collar 224 in the z reference direction. For comparison's sake, in FIG. 3A the core 220 is at the top of the collar 224 and in FIG. 3B the core 220 is at the bottom of the collar 224. The downward movement of the core 220 caused by the magnet 302 results in a smaller diameter of the taper 234 adjacent to the bulbous portions 230 of the locking nubs 218. This allows the locking nubs 218 to move inwardly slightly in the xy reference plane. Stated another way, the (unbiased) outside-to-outside dimension D3 between opposing locking nubs 218 is smaller in FIG. 3B in the presence of the magnet 302 than the (biased) outside-to-outside dimension D1 in FIG. 3A without the magnet. This smaller dimension D3 will allow insertion of foot assembly 110 into the receptacle 112 as will be illustrated relative to FIG. 3C.

As used here, the ‘biased’ outer or outside-to-outside dimension D1 occurs when the spring 240 is biasing the core 220 upward so that a larger diameter of the taper 234 is forced against the locking nubs 218 and forces the locking nubs outwards in the xy reference plane. The “unbiased” outer dimension D3 occurs when the magnetic field overcomes the upward spring bias and a smaller diameter of the core's taper 234 contacts the locking nubs 218 so that the locking nubs can move inwardly along the xy reference plane.

FIG. 3C shows the magnet 302 remaining on the foot assembly 110 and continuing to provide a magnetic force that moves the core 220 downward. At this point, the foot assembly is being inserted upwardly into the receptacle 112. The bulbous portions 230 are passing through the constraint of the ring 204. The ring 204 is forcing the locking nubs 218 inwardly against the core 220. The outside dimension as measured across the bulbous portions (e.g., dimension D3 of FIG. 3B) is essentially equal to or slightly smaller than the inside dimension defined by the ring 204 (e.g., dimension D2 of FIG. 3A).

FIG. 3D shows the foot assembly 110 fully inserted into the receptacle 112 with the magnet 302 still attached to the foot assembly. With the foot assembly 110 fully inserted into the receptacle 112, the locking nubs 218 are past the ring 204 and in the volume 206. At this point, the widest part/portion of the bulbous portions 230 that define the dimension D3 have passed and are above the ring 204.

FIG. 3E shows the foot assembly 110 in the same location in the receptacle 112 as FIG. 3D. However, the magnet has been removed from the foot assembly 110. Without the magnetic force acting on the core 220 and pulling the core downward, the spring 240 has once again biased the core 220 upward. The upward movement of the core is reflected in the presence of the core in collar 224 rather than below the collar as in FIG. 3D. The upward movement of the core 220 caused the taper 234 to contact the locking nubs 218 and force the locking nubs outward (e.g., the outside-to-outside dimension of the locking nubs is now equivalent to D1 of FIG. 3A),

With the core 220 in the illustrated position of FIG. 3E relative to the z reference direction, the core 220 is locking the locking nubs 218 into the same position as FIG. 3A. The locking nubs 218 cannot move inwardly (e.g., toward one another or toward the z reference axis or dimension) in the xy reference plane without the core 220 moving downwardly. However, spring 240 is creating an upward bias force on the core 220 that prevents any downward movement of the core. In this configuration, the bulbous portions 230 of the locking nubs 218 have returned to the dimension D1 labelled in FIG. 3A, which is greater than the ring dimension D2 labelled in FIG. 3A. Thus, the locking nubs 218 are physically blocking downward movement (e.g., removal) of the foot assembly 110 from the receptacle 112.

The locking nubs 218, in combination with the tapered core 220, provide a technical solution of defining the outer dimension of the foot assembly 110 in the volume 206 above the constraint provided by the ring 204. The outer dimension controls whether the foot assembly 110 is locked in the receptacle 112 or can be removed. The technical solution is achieved by the locking nubs 218 in that the elongate portions 232 retain the locking nubs 218 between the core 220 and the outer shell 216. The bulbous portions 230 are moved radially inward and outwardly by the dimension of the taper 234 that contacts them. This radial movement controls whether the outside dimension of the foot assembly 110 is greater than or less than the constraint of the receptacle 112 (e.g., the inner dimension of the ring 204).

Thus, in this technical solution, the locking nubs 218 are fixed in the z reference direction, but can move inwardly and outwardly in the xy reference plane when contacting the taper 234 to define the outer dimension of the foot assembly 110 in the volume 206 bounded by ring 204. This technical solution also enables touchless ‘locking’ and ‘unlocking’ of the locking mechanism 208 by the magnet 302. Thus, this configuration allows a seamless exposed pad 214 (e.g., no opening or tool hole) to allow the locking mechanism 208 to be locked or unlocked. In fact, in this technical solution the locking mechanism 208 can be locked and unlocked by the presence or absence of the magnetic field without ever physically touching the locking mechanism. From another perspective, this technical solution is achieved without the use of fasteners, such as screws to attach the foot assembly to the device so no physical access is required through the seamless exposed pad 214 and there are no fasteners to come loose and/or lose.

FIGS. 4A-4E collectively show the function of the foot assembly 110. FIG. 4A shows the foot assembly 110 installed in the receptacle 112 as shown in FIG. 3E. At this point, the spring 240 is expanding to a height H1 and imparting a bias force on the core 220. The bias force of the spring 240 is forcing core 220 upward into collar 224. This increases the diameter of the taper 234 acting on the locking nubs 218. The taper 234 is pushing the locking nubs 218 outward radially and blocking them from moving inwardly even if the locking nubs were exposed to inward forces. Thus, the locking nubs 218, which have the biased outside diameter that is greater than an inside diameter of the ring 204, mechanically block the foot assembly 110 from being removed from the receptacle 112.

FIG. 4B shows how the foot assembly 110 can be unlocked and removed from the receptacle 112 with the aid of magnet 302. The magnet 302 is positioned against the exposed pad 214. The magnet 302 creates an attractive magnetic force on the ferrous core 220. The attractive magnetic force overcomes the upward bias force of the spring 240 and pulls the core 220 downward and compresses the spring. This is evidenced in that the height of the compressed spring H2 is less than the spring height H1 of FIG. 4A. The downward movement of the core 220 exposes a smaller diameter of the taper 234 to the bulbous portions 230. This allows the locking nubs 218 to move inwardly so that the outside dimension of the bulbous portions 230 is equal to or less than a diameter defined by ring 204.

FIG. 4C shows partial removal of the foot assembly 110 from the receptacle 112. At this point the bulbous portions 230 of the locking nubs 218 are passing by the ring 204 as the foot assembly 110 is moving in the negative z reference direction relative to the receptacle. For instance, the weight of the foot assembly 110 and the magnet 302 may be sufficient to create the downward movement. Alternatively or additionally, a user who places the magnet on the foot assembly can impart a downward force on the magnet.

FIG. 4D shows the foot assembly 110 removed or un-installed from the receptacle 112 and still attached to the magnet 302. At this point, the magnetic force continues to pull the core 220 downward and compress the spring 240.

FIG. 4E shows the magnet removed from the foot assembly 110. The spring 240 has once again expanded and forced the core 220 upward into the collar 224. This is equivalent to the starting position shown in FIG. 3A. The sequence described above explains the technical benefit offered by the tapered core 220. In this technical solution, the spring 240 and the magnet 302 control the position of the tapered core 220 in the z reference direction and hence the diameter of the tapered core acting on the locking nubs 218. The tapered core 220 translates this z reference direction position into radial movement of the locking nubs 218 in the xy plane which in turn controls whether the foot assembly 110 is locked in the receptacle 112 (e.g., locked position) or can be removed (e.g., unlocked position).

The present concepts can be utilized with various types of computing devices that can employ secure part retention. The computing devices can include, but are not limited to, notebook computers, tablet type computers, smart phones, wearable smart devices, gaming devices, entertainment consoles, and/or other developing or yet to be developed types of devices. As used herein, a computing device can be any type of device that has some amount of processing and/or storage capacity and/or other heat generating components.

Various examples are described above. Additional examples are described below. One example includes a device comprising a housing containing electronic components, a receptacle positioned in the housing, and a foot assembly positioned in the receptacle, the foot assembly including a locking mechanism that mechanically blocks removal of the foot assembly from the receptacle unless acted upon by a magnetic field that rearranges the locking mechanism and unblocks removal of the foot assembly from the receptacle.

Another example can include any of the above and/or below examples where the receptacle defines a volume that is bounded in part by a ring.

Another example can include any of the above and/or below examples where the locking mechanism is inserted past the ring into the volume.

Another example can include any of the above and/or below examples where the locking mechanism mechanically blocks removal of the foot assembly by having an outer dimension that is greater than an inside dimension of the ring.

Another example can include any of the above and/or below examples where the locking mechanism includes an outer shell that defines a collar and radially arranged holes.

Another example can include any of the above and/or below examples where the locking mechanism further comprises locking nubs that are positioned in the radially arranged holes.

Another example can include any of the above and/or below examples where the locking nubs collectively define the outer dimension.

Another example can include any of the above and/or below examples where the locking nubs comprise an elongate portion and a bulbous portion.

Another example can include any of the above and/or below examples where the locking mechanism further comprises a core that is received in a second volume defined by the outer shell.

Another example can include any of the above and/or below examples where the core is tapered and a position of the core in the second volume determines a position of the locking nubs and the outer dimension.

Another example can include any of the above and/or below examples where the locking mechanism further comprises a biasing member that imparts a biasing force on the core into the second volume defined by the outer shell.

Another example can include any of the above and/or below examples where the biasing force forces the core farther into the outer shell and causes the taper to contact the locking nubs.

Another example can include any of the above and/or below examples where the biasing member comprises a spring.

Another example can include any of the above and/or below examples where the core comprises a ferrous material.

Another example can include any of the above and/or below examples where outer shell and the locking nubs comprise a non-ferrous material.

Another example can include any of the above and/or below examples where the magnetic field overcomes the bias and pulls the core part way out of the outer shell.

Another example includes a device comprising a housing including a receptacle that defines a constraint between an opening and an internal volume and a foot assembly comprising an over-molded cover positioned outside the receptacle and a locking mechanism extending along an axis through the opening and the constraint into the volume, the locking mechanism having an unbiased outer dimension measured transverse the axis that is less than an internal dimension defined by the constraint, the foot assembly further comprising a spring configured to create a bias that causes a biased outer dimension of the locking mechanism to be greater than an inner dimension of the constraint.

Another example can include any of the above and/or below examples where the locking mechanism comprises a tapered core that is biased along the axis by the spring, and wherein the tapered core acts upon locking nubs that collectively define the outer dimension.

Another example can include any of the above and/or below examples where the device further comprising a removable magnet positioned against the foot assembly that is configured to overcome the bias and maintain the unbiased outer dimension that is less than the inner dimension of the constraint.

Another example includes a device comprising a receptacle defining a ring interposed between a volume and an opening along an axis and a foot assembly comprising an exposed pad positioned outside the opening and a locking mechanism extending from the exposed pad into the volume, the locking mechanism comprising a biasing member nested in a tapered core that is nested in an outer shell, the locking mechanism further comprising locking nubs captured between and extending through holes in the outer shell, the biasing member producing a biasing force on the tapered core along the axis that forces and locks the nubs outward through the holes to lock the foot assembly in the receptacle above the ring.

### CONCLUSION

Although techniques, methods, devices, systems, etc., pertaining to secure part retention are described in language specific to structural features and/or methodological acts, it is to be understood that the subject matter defined in the appended claims is not necessarily limited to the specific features or acts described. Rather, the specific features and acts are disclosed as example forms of implementing the claimed methods, devices, systems, etc.

1. A device (102), comprising:
a housing (104) containing electronic components (106);
a receptacle (112) positioned in the housing; and,
a foot assembly (110) positioned in the receptacle, the foot assembly including a locking mechanism (208) that mechanically blocks removal of the foot assembly from the receptacle unless acted upon by a magnetic field that rearranges the locking mechanism and unblocks removal of the foot assembly from the receptacle.

2. The device of claim 1, wherein the receptacle defines a volume (206) that is bounded in part by a ring (204).

3. The device of claim 2, wherein the locking mechanism is inserted past the ring into the volume.

4. The device of claim 3, wherein the locking mechanism mechanically blocks removal of the foot assembly by having an outer dimension that is greater than an inside dimension of the ring.

5. The device of claim 4, wherein the locking mechanism includes an outer shell (216) that defines a collar (224) and radially arranged holes (222).

6. The device of claim 5, wherein the locking mechanism further comprises locking nubs (218) that are positioned in the radially arranged holes.

7. The device of claim 6, wherein the locking nubs collectively define the outer dimension.

8. The device of claim 7, wherein the locking nubs comprise an elongate portion (232) and a bulbous portion (230).

9. The device of claim 8, wherein the locking mechanism further comprises a core (220) that is received in a second volume (228) defined by the outer shell.

10. The device of claim 9, wherein the core is tapered (234) and a position of the core in the second volume determines a position of the locking nubs and the outer dimension.

11. The device of claim 10, wherein the locking mechanism further comprises a biasing member (210) that imparts a biasing force on the core into the second volume defined by the outer shell.

12. The device of claim 11, wherein the biasing force forces the core farther into the outer shell and causes the taper to contact the locking nubs.

13. The device of claim 12, wherein the biasing member comprises a spring.

14. The device of claim 13, wherein the core comprises a ferrous material.

15. A device (102), comprising:
a receptacle (112) defining a ring (204) interposed between a volume (206) and an opening (200) along an axis; and,
a foot assembly (110) comprising an exposed pad (214) positioned outside the opening and a locking mechanism (208) extending from the exposed pad into the volume; and,
the locking mechanism comprising a biasing member (210) nested in a tapered core (220) that is nested in an outer shell (216), the locking mechanism further comprising locking nubs (218) captured between and extending through holes (222) in the outer shell, the biasing member producing a biasing force on the tapered core along the axis that forces and locks the nubs outwardly through the holes to lock the foot assembly in the receptacle above the ring.
